(19) United States
(12) Patent Application Publication
(10) Pub. No.: US 2013/0034965 A1
(43) Pub. Date: Feb. 7, 2013

(54) METHODS OF FORMING FINE PATTERNS USING DRY ETCH-BACK PROCESSES

(71) Applicants: Hyoung-Hee KIM, Hwaseong-si (KR); Yool Kang, Yongin-si (KR); Song-Se Yi, Seoul (KR); Young-Ho Kim, Seongnam-si (KR); Jae-Ho Kim, Yongin-si (KR)

(72) Inventors: Hyoung-Hee KIM, Hwaseong-si (KR); Yool Kang, Yongin-si (KR); Song-Se Yi, Seoul (KR); Young-Ho Kim, Seongnam-si (KR); Jae-Ho Kim, Yongin-si (KR)

(73) Assignee: Samsung Electronics Co., Ltd.

(21) Appl. No.: 13/564,611

(22) Filed: Aug. 1, 2012

(30) Foreign Application Priority Data
Aug. 3, 2011 (KR) 10-2011-0077413

(51) Int. Cl. H01L 21/308

(52) U.S. Cl. 438/703; 257/E21.232

(57) ABSTRACT

In a method of fabricating patterns in an integrated circuit device, first mask patterns, sacrificial patterns, and second mask patterns are formed on a target layer such that the sacrificial patterns are provided between sidewalls of adjacent ones of the first and second mask patterns. The sacrificial patterns between the sidewalls of the adjacent ones of the first and second mask patterns are selectively removed using a dry etch-back process, and the target layer is patterned using the first and second mask patterns as a mask.

### CROSS-REFERENCE TO RELATED APPLICATION

This application claims priority under 35 U.S.C. §119 to Korean Patent Application No. 10-2011-0077413 filed on Aug. 3, 2011, the disclosure of which is hereby incorporated by reference in its entirety.

### BACKGROUND

Embodiments of the inventive concept relate to methods of forming patterns of an integrated circuit device.

In order to form fine patterns in integrated circuit devices, various methods have been suggested, and research into techniques for overcoming obstacles to a photolithography process has been undertaken.

### SUMMARY

Embodiments of the inventive concept provide methods of forming fine patterns during a process of fabricating a semiconductor device.

Embodiments of the inventive concept provide methods of forming dual patterns during a process of fabricating a semiconductor device.

Embodiments of the inventive concept provide methods of forming patterns using organic materials during a process of fabricating a semiconductor device.

Embodiments of the inventive concept provide methods of forming dual patterns using organic materials during a process of fabricating a semiconductor device.

Embodiments of the inventive concept provide methods of fabricating flash memory devices.

Embodiments of the inventive concept provide methods of fabricating NAND flash memory devices including floating gates.

Embodiments of the inventive concept provide methods of fabricating NAND flash memory devices including charge trap insulating materials.

Embodiments of the inventive concept provide memory modules and electronic systems including integrated circuit devices fabricated according to the inventive concept.

Aspects of the inventive concept should not be limited by the above description, and other unmentioned aspects will be clearly understood by one of ordinary skill in the art from example embodiments described herein.

According to some embodiments, a method of fabricating patterns in an integrated circuit device includes forming first mask patterns, sacrificial patterns, and second mask patterns on a target layer such that the sacrificial patterns are provided between sidewalls of adjacent ones of the first and second mask patterns; selectively removing the sacrificial patterns between the sidewalls of the adjacent ones of the first and second mask patterns using a dry etch-back process; and patterning the target layer using the first and second mask patterns as a mask.

In some embodiments, one or more of the first mask patterns, the second mask patterns, and the sacrificial patterns may be organic materials.

In some embodiments, the sacrificial patterns may have a lower carbon content and/or a higher oxygen content than the first mask patterns.

In some embodiments, the dry etch-back process may be a plasma etch-back process. The dry etching process may employ a removal gas, such as oxygen. The dry etching process may also employ a protection gas, such as hydrogen bromide and/or chlorine.

In some embodiments, the first mask patterns may be photolithographically formed from a photoresist material containing an acid or generator thereof. The second mask patterns may be a material having a similar dry etching resistance to that of the first mask patterns. The sacrificial patterns may be a material configured to react with the acid to form an ionic bond.

In some embodiments, forming the sacrificial patterns may include: forming a sacrificial layer on upper surfaces and sidewalls of the first mask patterns; processing the first mask patterns and the sacrificial layer thereon such that the acid diffuses into portions of the sacrificial layer on the upper surfaces and sidewalls of the first mask patterns and reacts therewith; and selectively removing unreacted portions of the sacrificial layer to define the sacrificial patterns along the upper surfaces and sidewalls of the first mask patterns. The sacrificial layer may include a water soluble polymeric organic compound containing carbon, nitrogen, and/or hydrogen, such as pyrrolidone and/or imidazole.

In some embodiments, an anti-reflective layer including an organic material may be formed on the target layer prior to forming the first mask patterns thereon. Selectively removing the sacrificial patterns may further remove portions of the anti-reflective layer thereon.

In some embodiments, forming the second mask patterns may include: forming a second mask layer on the first mask patterns and the sacrificial patterns; forming an acid generation layer on the second mask layer; processing the acid generation layer and the second mask layer such that acid diffuses into portions of the second mask layer and reacts therewith to define a soluble layer; and removing the acid generation layer and the soluble layer to define the second mask patterns.

In some embodiments, removing the soluble layer may include selectively removing the soluble layer using a chemical etch-back process including alkali chemicals or developers containing tetramethylammonium hydroxide (TMAH).

In some embodiments, the first and second mask patterns may have a higher dissolving resistance to the alkali chemicals than the sacrificial patterns.

In some embodiments, the target layer may include at least one hard mask layer and a lower layer on a substrate. The target layer may be patterned by patterning the at least one hard mask layer using the first and second mask patterns to define hard mask patterns on the lower layer, and patterning the lower layer using the hard mask patterns to define lower layer patterns.

In some embodiments, the substrate may also be patterned using the hard mask patterns as a mask to define trenches therein. Isolating insulation patterns may be formed in the trenches between adjacent ones of the lower layer patterns; and an upper conductive layer may be formed on the lower layer patterns and the isolating insulation patterns.

In some embodiments, the lower layer patterns may respectively include a lower insulating pattern and a lower conductive pattern thereon. An intermediate insulating layer may be formed on the lower conductive patterns and the isolating insulation patterns prior to forming the upper conductive layer thereon. The upper conductive layer may define a floating gate pattern and the conductive patterns may define control gate patterns of a flash memory device.

In some embodiments, the lower layer patterns may respectively include a stack including a lower trap insulating pattern, an intermediate trap insulating pattern, and an upper trap insulating pattern to define a charge trap flash memory device.

In some embodiments, the target layer may be an insulating layer on a substrate, and the target layer may be patterned to define insulating patterns on the substrate. Conductive patterns may be formed on the substrate between the insulating patterns.

In accordance with further embodiments of the inventive concept, a method of forming patterns includes forming a lower layer on a substrate, forming first mask patterns on the lower layer, forming sacrificial patterns on surfaces of the first mask patterns, forming second mask patterns between the sacrificial patterns, removing the sacrificial patterns using a dry etch-back process to expose the first mask patterns, patterning the lower layer using the first and second mask patterns as masks to form lower patterns, and removing the first and second mask patterns.

In some embodiments, the method may further include forming an anti-reflection layer containing an organic material between the lower layer and the first mask patterns, and forming anti-reflection patterns by patterning the anti-reflection layer at the same time the sacrificial patterns are removed.

In some embodiments, the first mask patterns may include a photoresist material containing acid or potential acid, and the second mask patterns may include an organic material that does not contain acid or potential acid.

In some embodiments, the first and second mask patterns may have a higher dissolving resistance to an alkali dissolvent than the sacrificial patterns.

In some embodiments, forming the sacrificial patterns may include forming a sacrificial layer covering the surfaces of the first mask patterns, converting a partial region of the sacrificial layer adjacent to the first mask patterns into sacrificial patterns, and removing the other region of the sacrificial layer that is not converted into the sacrificial patterns.

In some embodiments, converting the partial region of the sacrificial layer into the sacrificial patterns may include diffusing acid in the first mask patterns into the sacrificial layer using a baking process, and reacting the diffused acid with the sacrificial layer.

In some embodiments, the sacrificial layer may include a water soluble polymeric organic compound containing pyrrolidone or imidazole, or containing carbon, nitride and/or hydrogen.

In some embodiments, forming the second mask patterns may include forming a mask material layer on the sacrificial patterns, and removing an upper part of the mask material layer to expose upper parts of the sacrificial patterns.

In some embodiments, removing the upper part of the mask material layer may include forming an acid generation layer containing acid or potential acid on the mask material layer, generating acid in the acid generation layer, diffusing the generated acid into the mask material layer to form a soluble layer, and removing the soluble layer.

In some embodiments, the potential acid may include a thermo acid generator (TAG), and the generating acid in the acid generation layer and diffusing the generated acid into the mask material layer may include using a baking process.

In some embodiments, the baking process may include placing the substrate including the acid generation layer in a bake oven having a temperature lower than a glass-transition temperature of the mask material layer for about 30 seconds to about 2 minutes.

In some embodiments, removing the soluble layer may include using alkali chemicals or developers containing tetramethylammonium hydroxide (TMAH).

In some embodiments, the dry etch-back process may include a plasma process including a removal gas for removing the sacrificial patterns, and a hardening gas for hardening the sacrificial patterns.

In some embodiments, the removal gas may include oxygen gas (O₂), and the hardening gas includes hydrogen bromide (HBr) gas.

In accordance with still further embodiments of the inventive concept, a method of forming patterns includes forming a lower layer on a substrate, forming a hard mask layer on the lower layer, forming a first mask pattern, a second mask pattern spaced apart from the first mask pattern, and a sacrificial pattern between the first and second mask patterns on the hard mask layer, removing the sacrificial pattern using a gas plasma process containing oxygen, patterning the hard mask layer using the first and second mask patterns as masks to form a hard mask pattern, and patterning the lower layer using the hard mask pattern as a mask to form a lower pattern.

Particulars of further embodiments are described herein in greater detail with reference to the detailed descriptions and drawings.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1A through 1D and 2A through 5 are flowcharts and cross-sectional views illustrating methods of forming patterns according to first to fourth embodiments of the inventive concept;

FIGS. 6A through 6G are cross-sectional views illustrating methods of forming patterns according to a fifth embodiment of the inventive concept;

FIGS. 7A through 7E are cross-sectional views illustrating methods of forming patterns according to a sixth embodiment of the inventive concept;

FIGS. 8A through 8D are cross-sectional views illustrating methods of forming patterns according to a seventh embodiment of the inventive concept; and

FIG. 9A is a module block diagram of an integrated circuit device module according to some embodiments of the inventive concept, and FIG. 9B is a system block diagram of an electronic system according to further embodiments of the inventive concept.

### DETAILED DESCRIPTION OF EMBODIMENTS

Advantages, features, and methods of achieving the same in accordance with the present inventive concept will now be described more fully with reference to the accompanying drawings in which some embodiments are shown. This inventive concept may, however, be embodied in different forms and should not be construed as limited to the embodiments set forth herein. Rather, these embodiments are provided so that this disclosure is thorough and complete and fully conveys the scope of the inventive concept to those skilled in the art. In the drawings, the thickness of layers and regions may be exaggerated for clarity.

It will be understood that when an element or layer is referred to as being “connected to,” or “coupled to” another element or layer, it can be directly connected to or coupled to another element or layer or intervening elements or layers may be present. In contrast, when an element is referred to as being “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present inventive concept.

Spatially relative terms, such as “beneath”, “below”, “lower”, “under”, “above”, “upper,” “over” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” or “over” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the inventive concept are described herein with reference to cross-section illustrations that are schematic illustrations of idealized embodiments (and intermediate structures) of the inventive concept. As such, variations from the shapes of the illustrations as a result, for example, of manufacturing techniques and/or tolerances, are to be expected. Thus, embodiments of the inventive concept should not be construed as limited to the particular shapes of regions illustrated herein but are to include deviations in shapes that result, for example, from manufacturing. Accordingly, the regions illustrated in the figures are schematic in nature and their shapes are not intended to illustrate the actual shape of a region of a device and are not intended to limit the scope of the inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

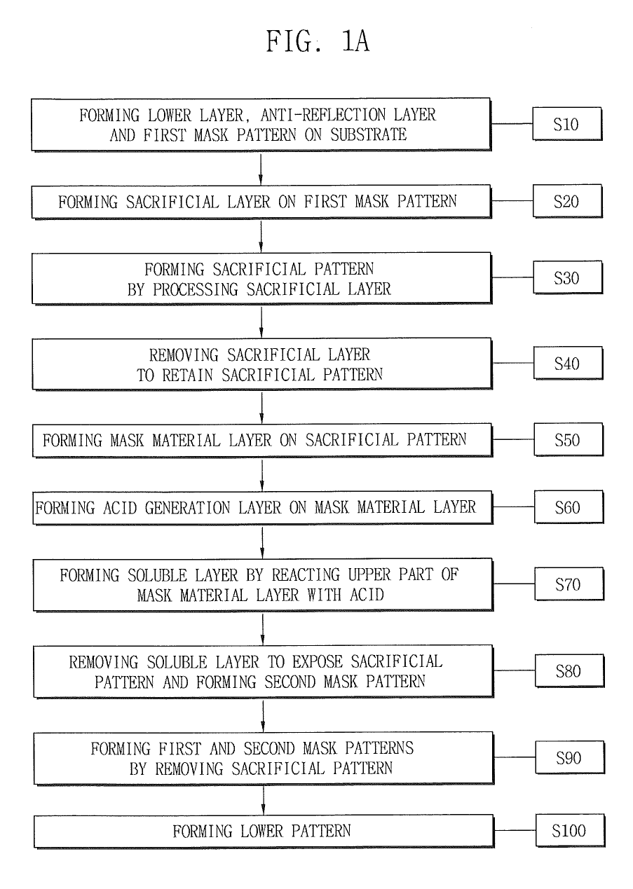

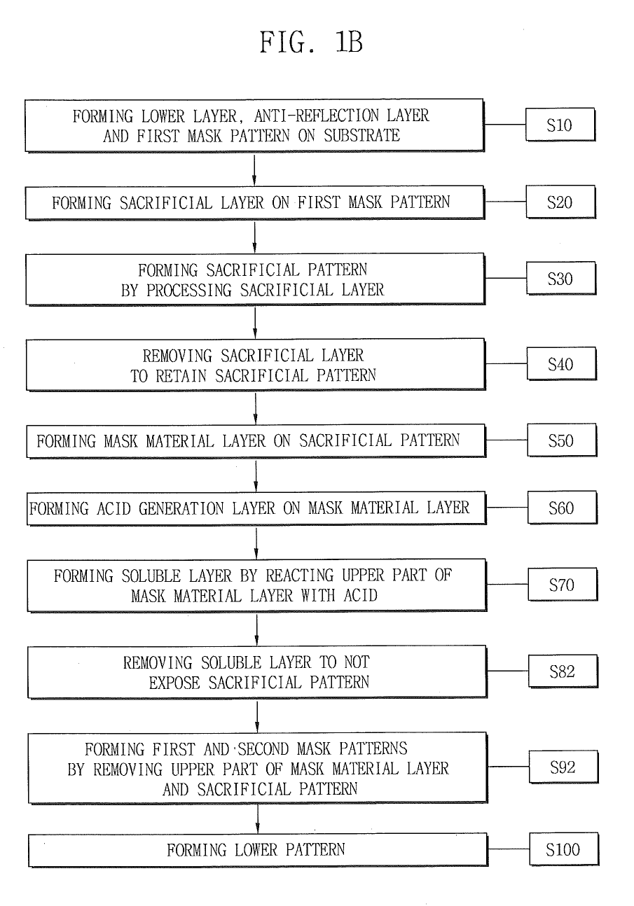

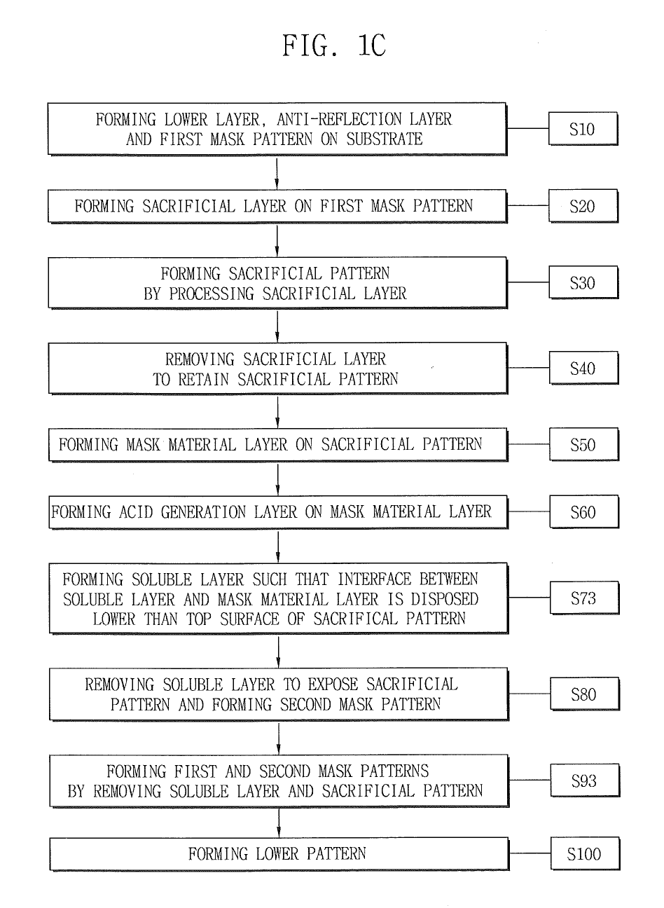

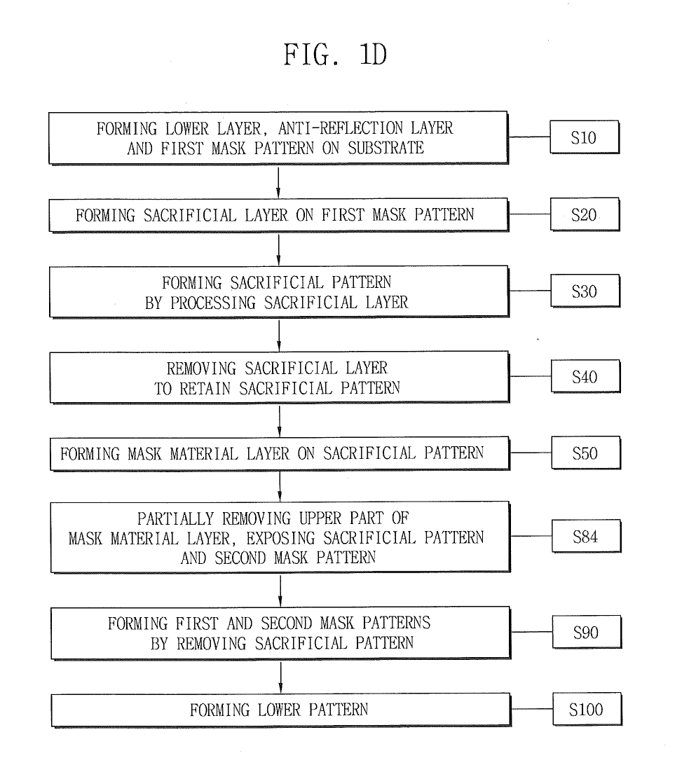

FIGS. 1A through 1D and 2A through 5 are flowcharts and cross-sectional views of methods of forming patterns according to various embodiments of the inventive concept.

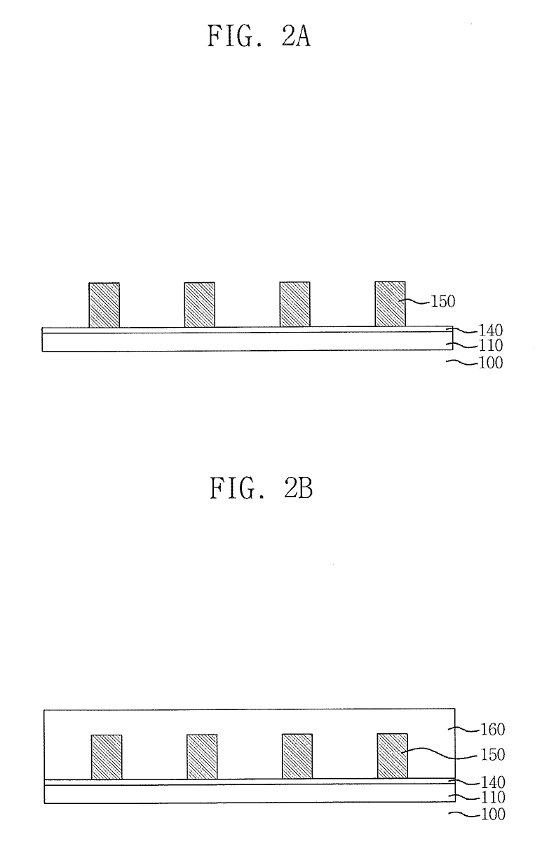

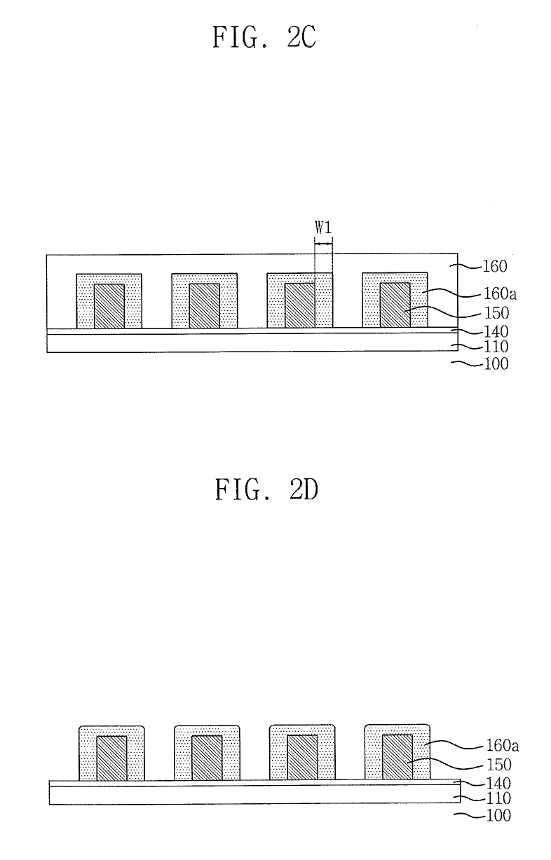

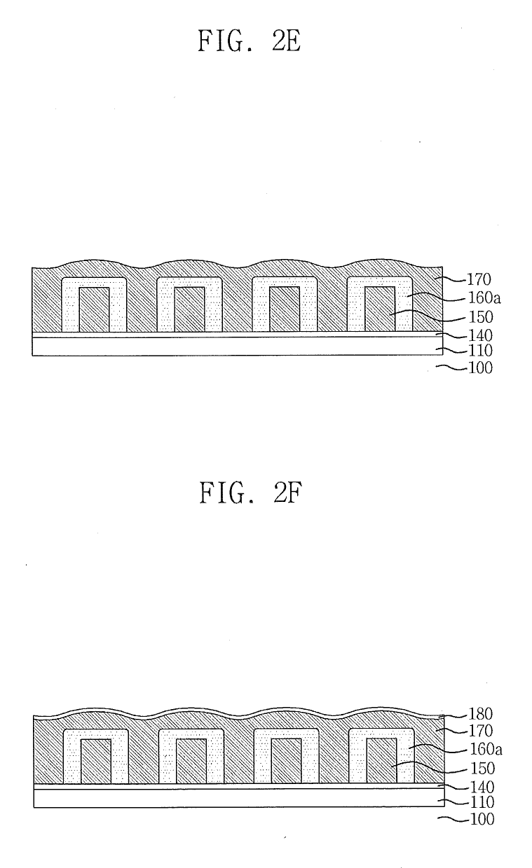

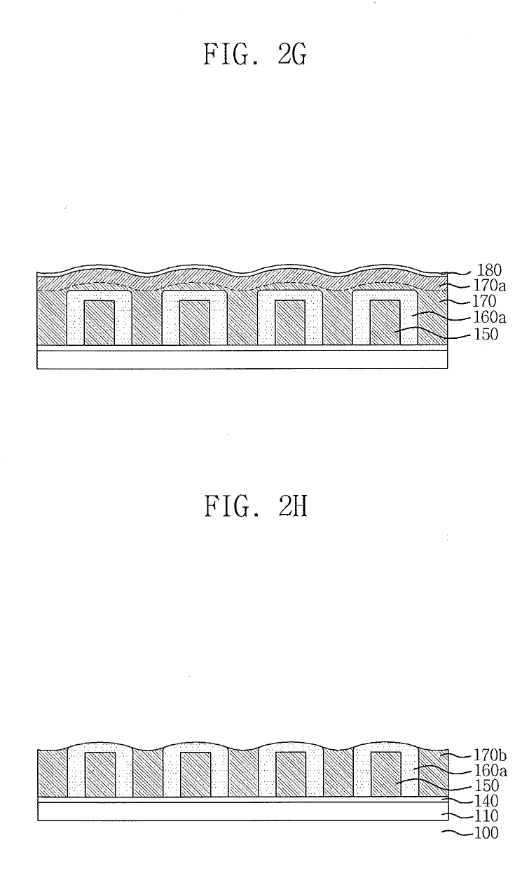

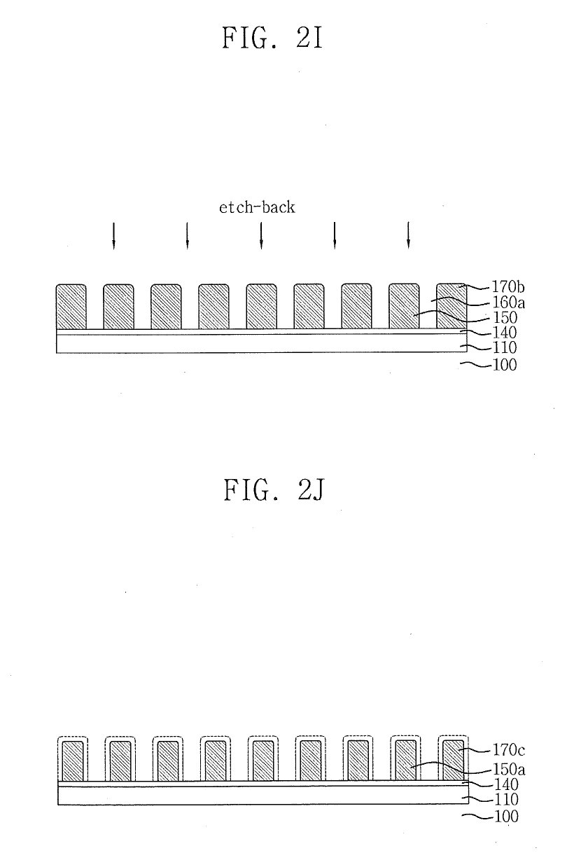

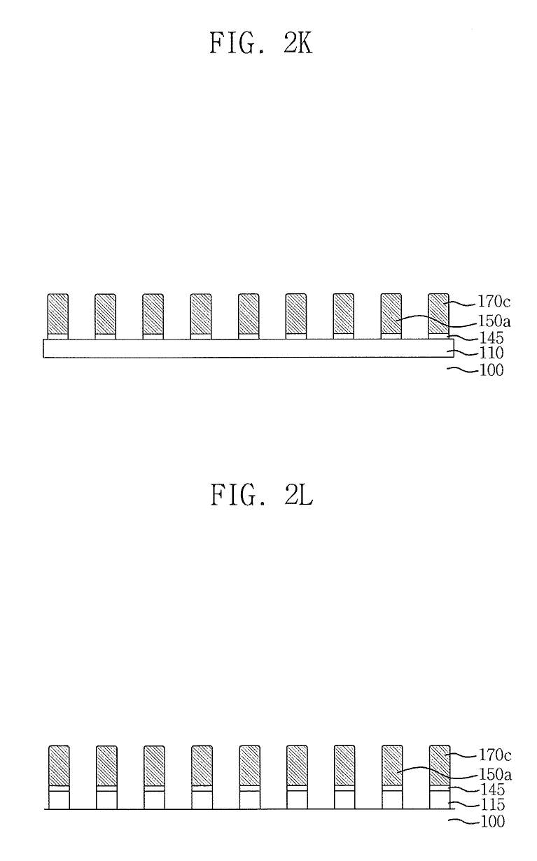

Referring to FIGS. 1A and 2A, methods of forming patterns according to a first embodiment of the inventive concept may include forming a lower or target layer 110, an anti-reflection layer 140 and a first mask pattern 150 on a substrate 100 (S10). The first mask pattern 150 may also be referred to as a first mask layer. Reference numeral 150 is referred to as the first mask pattern 150 for clarity.

In embodiments of the inventive concept, the substrate 100 may include various types such as a single crystalline wafer, a germanium containing silicon wafer, a silicon on insulator (SOI) wafer, ceramic and/or glass. Additionally or alternatively, the substrate 100 may be an insulating layer or a conductive layer formed below the lower layer 110. In the specification, for clarity, an element represented by reference numeral 100 is regarded as a wafer, etc.

The lower layer 110 may include various materials such as silicon, silicon oxide, silicon nitride, and/or metals. The lower layer 110 may be variously formed depending on the particular process for forming patterns that is used. For example, when it is desired to form gate patterns, the lower layer 110 may include a gate electrode material layer or a gate capping material layer. Alternatively, when it is desired to form a string of a flash memory device, the lower layer 110 may include various materials such as a charge storage material layer, a tunneling insulating material layer, a blocking material layer, an inter-gate insulating layer, a gate electrode material layer, and/or a gate capping material layer. Therefore, the lower layer 110 may be formed by various methods such as a chemical or physical deposition method, a coating method, a growth method and/or a plating method. Various materials or structures may be further interposed between the substrate 100 and the lower layer 110. Detailed examples of the lower layer 110 are described herein; however, the lower layer 110 is not limited thereto, and may include any desired materials to be patterned in accordance with embodiments of the inventive concept.

During a photolithography process for forming the first mask pattern 150, the anti-reflection layer 140 may absorb light reflected from a surface or interface of the substrate 100 and/or lower layer 110, and/or may offset the light using an interference effect. The anti-reflection layer 140 may include an organic coating layer or an inorganic deposition layer. For example, the anti-reflection layer 140 may include an organic polymer or an inorganic material such as SiON. When the anti-reflection layer 140 includes an organic material, the anti-reflection layer 140 may be formed using a coating method, and when the anti-reflection layer 140 includes an inorganic material, the anti-reflection layer 140 may be formed using a deposition method. In the embodiments described herein, the anti-reflection layer 140 includes an organic material by way of example. When the anti-reflection layer 140 includes an organic material, footing or lifting due to poor adhesion between a mask material for forming the first mask pattern 150 (i.e., a photoresist material) and the lower layer 110 may be reduced and/or prevented. As such, negative effects that may result from processes that may be used to improve the adhesion between the lower layer 110 and the photoresist may be reduced and/or prevented. For example, processes that may be used to improve adhesion properties between the lower layer 110 and the photoresist may exhaust or involve an alkaline solvent or a reactor to interfere with the patterning of the photoresist. Therefore, when the anti-reflection layer 140 includes an organic material, processes to improve adhesion properties between the lower layer 110 and the photoresist may be omitted, and such processes to improve adhesion between the lower layer 110 and the anti-reflection layer 140 may not affect the photoresist process. Also, the use of an anti-reflection layer 140 formed of an organic material may not require an additional patterning processes, as the anti-reflection layer 140 including the organic material may be removed at the same time other organic materials are removed, as described in greater detail below.

The first mask pattern 150 may be a photoresist pattern. Therefore, the first mask pattern 150 may be formed by forming a photoresist layer on the lower layer 110, and by performing photolithography processes including exposing, baking, and developing processes. Therefore, the first mask pattern 150 may include a base resin and an acid or potential acid. The potential acid may include a photo acid generator (PAG) or a thermo acid generator (TAG).

The first mask pattern 150 may selectively expose a top or upper surface of the anti-reflection layer 140. Viewed from a plan view, the first mask pattern 150 may be variously formed such as in the shape of a line, a bar, a box or an island. In some embodiments described herein, the first mask pattern 150 is exemplified to be in the shape of a line in a plan view.

Referring to FIGS. 1A and 2B, the method of forming patterns according to the first embodiment of the inventive concept may include forming a sacrificial layer 160 covering the first mask pattern 150 (S20). The sacrificial layer 160 may include a water soluble polymeric organic compound. The sacrificial layer 160 may include a polymeric organic compound containing C, N, and/or H. For example, the sacrificial layer 160 may include a compound containing pyrrolidone represented by the following Formulae 1 and 2, and/or a polymeric organic compound containing imidazole.

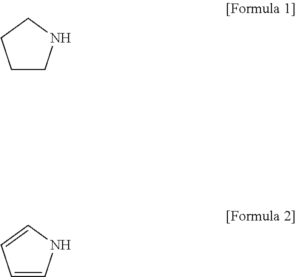 [SMILES: C1CCNC1 ; c1cc[nH]c1]

The sacrificial layer 160 may react with acid (H) to form an ionic bond. The sacrificial layer 160 may react with the acid to be attached to a surface of the first mask pattern 150.

The sacrificial layer 160 may exhibit significantly lower carbon (C) content than the first mask pattern 150. Additionally or alternatively, the sacrificial layer 160 may exhibit relatively higher oxygen (O) content than the first mask pattern 150. When the carbon content is relatively low or the oxygen content is relatively high, dry etch resistance may be relatively lowered. That is, the removal rate by dry etching may be relatively increased. Dry etch resistance is proportional to a value obtained by subtracting the total number of oxygen atoms from the total number of carbon atoms that each material contains, and dividing the results by the total number of atoms. That is, as the carbon atom content accounts for a great part of the total number of atoms, dry etch resistance increases, and as the oxygen atom content accounts for a great part thereof, dry etch resistance decreases. The content of carbon atom numbers and the content of oxygen atom numbers may have a relationship with dry etch resistance and the dry etching rate as indicated below (where the symbol “∝” refers to “is proportional to”).

[{(Total number of carbon atoms)−(Total number of oxygen atoms)}/(Total number of atoms)]∝Dry etch resistance

[(Total number of atoms)/{(Total number of carbon atoms)−(Total number of oxygen atoms)]∝Dry etching rate

Therefore, the sacrificial layer 160 may exhibit a relatively higher carbon atom content, or a relatively lower oxygen atom content, than the first mask pattern 150. The relative content may be variously adjusted according to the particular fabrication process being used. For example, a reactor, a substituent, or an additive containing oxygen may be added to a base resin during the process of fabricating the sacrificial layer 160. The amount of carbon atoms and oxygen atoms that the sacrificial layer 160 contains may be variously adjusted according to the process to be used. Basically, a water soluble polymeric compound containing the above-described compounds may have the lower dry etching resistance than the above exemplified photoresist.

Referring to FIGS. 1A and 2C, the method of forming patterns according to the first embodiment may include processing the sacrificial layer 160 to form a sacrificial pattern 160a (S30). The sacrificial pattern 160a may be formed to be on and/or surround one or more surfaces (such as upper and sidewall surfaces) of a first mask pattern 150. The formation of the sacrificial pattern 160a may include a first baking process. The first baking process, for example, may include placing the substrate 100 having the sacrificial layer 160 surrounding the first mask pattern 150 into a heating apparatus such as a bake oven, and heating the substrate 100 at a temperature of several tens to several hundreds of degrees for several tens of seconds to several minutes. Specifically, the formation may include applying heat having a temperature between about 80° C. and about 150° C. to the substrate 100 for about 30 seconds to about 2 minutes. The temperature of the first baking process may be lower than a glass-transition temperature (Tg) of the first mask pattern 150. In the above embodiments, the first baking process was performed for about one minute by placing the substrate 100 in a bake oven having an internal temperature of about 100° C.

During the performance of the first baking process, acid remaining in the first mask pattern 150 or generated from potential acid may be diffused into the sacrificial layer 160. The diffused acid may react with the sacrificial layer 160 to form an ionic bond. A part of the sacrificial layer 160 in which an ionic bond is formed may be converted into a sacrificial pattern 160a. The sacrificial pattern 160a may exhibit different solubilities with respect to the sacrificial layer 160 and a developer. In some embodiments, the developer may contain de-ionized water. Therefore, a part of the sacrificial layer 160 in which an ionic bond is formed may have dissolving resistance to water. In the drawings, a horizontal width W1 of the sacrificial pattern 160a is illustrated to be greater than a vertical thickness. This indicates that relatively more acid remaining in the first mask pattern 150 or generated from potential acid may be diffused in the horizontal direction. However, when the first mask pattern 150 does not contain the potential acid, since relatively less acid remains in the first mask pattern, the horizontal width of the sacrificial pattern 160a may be similar to the vertical width thereof. That is, the shape of the sacrificial pattern 160a may vary depending on various process factors of the first baking processes. In other words, the thickness W1 of the sacrificial pattern 160a may depend on various process factors.

Referring to FIGS. 1A and 2D, the method of forming patterns according to the first embodiment may include selectively removing the sacrificial layer 160 and retaining the sacrificial pattern 160a (S40). Therefore, the sacrificial pattern 160a may be exposed. The removal of the sacrificial layer 160 may include using water to remove the sacrificial layer 160 and to retain (e.g., without substantially removing) the sacrificial layer 160a. In some embodiments, the anti-reflection layer 140 may be exposed.

Referring to FIGS. 1A and 2E, the methods of forming patterns according to the first embodiment may include forming a mask material layer 170 on the sacrificial pattern 160a (S50). The mask material layer 170 may extend on and/or cover the sacrificial pattern 160a. The mask material layer 170 may contain a photoresist and/or a base resin of the photoresist. The base resin may contain an acid labile group that may be resolved in and/or substituted with acid. The mask material layer 170 may not contain acid or an acid generator. In embodiments of the inventive concept, since the mask material layer 170 is not patterned through the photolithography process, an acid or an acid generator is not contained therein. The mask material layer 170 may contain a base resin having the equivalent or similar dry etching resistance to the first mask pattern 150. The first mask pattern 150 and the mask material layer 170 may have a relatively higher dissolving resistance to the alkali dissolvent than the sacrificial pattern 160a, for reasons that will be described in greater detail below.

Referring to FIGS. 1A and 2F, methods of forming patterns according to the first embodiment may include forming an acid generation layer 180 on the mask material layer 170 (S60). The acid generation layer 180 may include nonaflicbutenesulfonicacid (NfBSA), camphorsulfonicacid (CSA), potential acid, a water soluble polymer, and/or deionized water. The potential acid may contain acid, a thermal acid generator (TAG), and/or a photo acid generator (PAG). Taking into account acid generation ability of the acid generation layer 180, acid reaction sensitivity of the mask material layer 170, and factors of an acid generation process, limiting the thickness of the acid generation layer 180 may be insignificant, and thus specific numerical values will not be stated herein. In the experiment, the acid generation layer 180 was formed to a thickness between about 20 and 400 Å using a coating method.

Referring to FIGS. 1A through 2G, the methods of forming patterns according to the first embodiment may include generating acid from the acid generation layer 180 to be diffused into the mask material layer 170, so that an upper part of the mask material layer 170 may be converted into a soluble layer 170a (S70). The process of generating acid from the acid generation layer 180 to be diffused into the mask material layer 170 may include a second baking process. In the second baking process, time and temperature may be adjusted with reference to the first baking process. The second baking process may include applying heat having a temperature of several tens to several hundreds of degrees to the acid generation layer 180 for several tens of seconds to several minutes. For example, the process may include applying heat having a temperature between about 80° C. and about 120° C. to the acid generation layer 180 for about thirty seconds to about two minutes. As a result of the second baking process, the acid generation layer 180 may be changed into a material that may be dissolved into or by an alkali solvent. Additionally or alternatively, after the completion of the second baking process, an additional rinsing process may be performed, so that residues of the acid generation layer 180 may be completely removed.

The soluble layer 170a may react with acid to be dissolved in an alkali solvent. Specifically, the soluble layer 170a is a part in which an acid labile group contained in a base resin of the mask material layer 170 is substituted with a hydroxyl group (—OH) by acid, so that dissolving resistance to the alkali dissolvent is significantly lowered.

An interface between the soluble layer 170a and the mask material layer 170 may be disposed above or higher than a top or upper surface of the sacrificial pattern 160a. However, the interface between the soluble layer 170a and the mask material layer 170 is not necessarily disposed above/higher than the top/upper surface of the sacrificial pattern 160a in some embodiments, for reasons that will be described in more detail with respect to further embodiments of the inventive concept below.

Further, the thickness of the soluble layer 170a may be adjusted to control the height or thickness of the second mask layer. This will also be described in more detail below with reference to further embodiments of the inventive concept.

Referring to FIG. 2H, the methods of forming patterns according to the first embodiment may include removing the soluble layer 170a to expose an upper part of the sacrificial pattern 160a, thereby forming a second mask pattern 170b (S80). The second mask pattern 170b may be formed between the sacrificial patterns 160a. The soluble layer 170a may be removed by alkali chemicals or developers containing about 1 to 5 wt % tetramethylammonium hydroxide (TMAH). This process may be understood as a dissolution or development process. This process may also be referred to as chemical etch-back. As previously described, when the first mask pattern 150 and the mask material layer 170 have a relatively higher dissolving resistance to an alkali dissolvent than the sacrificial pattern 160a, damage to the sacrificial pattern 160a during this process may be prevented or alleviated. Therefore, when the first mask pattern 150 and the mask material layer 170 exhibits a higher dissolving resistance than the sacrificial pattern 160a, better results may be expected.

During this process, the upper part of the sacrificial pattern 160a may be lowered. Also, a top surface of the second mask pattern 170b may be disposed at a similar level to that of the first mask pattern 150. Specifically, since the soluble layer 170a may be formed to a desired thickness and removed, the top surface of the second mask pattern 170b may be formed at a desired level, that is, such that the first and second mask patterns 150 and 170b may have a similar height. Accordingly, since the first mask pattern 150 and the second mask pattern 170b may be formed to a similar height, uniformity of the subsequent patterning process may be improved. More specifically, the first mask pattern 150 and the second mask pattern 170b may be used as an etching mask or a patterning mask during the subsequent etching process. One factor during the etching process is the etching resistance of the etching mask, and stability of etching resistance may be intimately associated with a vertical thickness of the etching mask. Therefore, etching masks having a uniform height as a whole can enable more uniform results of an etching process to be expected. In addition, during this process, since the dissolvent for removing the soluble layer 170a is used only to remove the soluble layer 170a, a relatively small amount thereof may be used. When the dissolvent is used in a relatively small amount, negative effects such as partial damage or removal of the sacrificial pattern 160a or the second mask pattern 170b due to infiltrating of the dissolvent into the interface between the sacrificial pattern 160a and the second mask pattern 170b may be reduced or prevented. In embodiments of the inventive concept, since a small amount of dissolvent is used, damage to the sacrificial pattern 160a and/or the second mask pattern 170b may not be significant or serious. Further, when the soluble layer 170a is removed, the upper part of the sacrificial pattern 160a may not be exposed in some embodiments, as described in more detail below.

Referring to FIGS. 1A and 2I, the method of forming patterns according to the first embodiment may include removing the sacrificial pattern 160a using an etch-back process (S90). The etch-back process may include a removal gas for removing the sacrificial pattern 160a and a protection gas for protecting the first and second mask patterns 150 and 170b. For example, the etch-back process may include a dry etch-back process containing oxygen (O₂) gas and hydrogen bromide (HBr) gas, e.g., a gas plasma process.

The etch-back process may be performed, for example, at a gas flow between about 100 and 600 seem in a chamber maintaining a pressure of about 50˜300 mTorr and a room temperature of about 120° C. or lower. When pressure or temperature is extremely high, selectivities of the sacrificial pattern 160a and the first and second mask patterns 150 and 170b may be degraded. In some embodiments of the inventive concept, the process may be performed at a gas flow of about 400 sccm in a chamber maintaining a pressure of about 100 mTorr and an internal temperature between about 30 and 40° C. for about 1 minute.

The dry etching process may further include nitrogen and/or an inert gas such as H₂, Ne, and Ar. In some embodiments, chlorine (Cl₂) gas may be used instead of hydrogen bromide (HBr) gas. As previously described, since the sacrificial pattern 160a exhibits a relatively lower carbon content than the first and second mask patterns 150 and 170b, the sacrificial pattern 160a may be removed earlier than the first and second mask patterns 150 and 170b by the plasma process containing O₂ gas and HBr gas. In the process, O₂ gas forms a substitution bond with carbon, so that a volatile polymer is formed. Further, HBr gas hardens the first and second mask patterns 150 and 170b to protect the first and second mask patterns 150 and 170b, so that etch-back selectivity and/or rate may be improved and controlled. That is, HBr gas may prevent the first and second mask patterns 150 and 170b and the sacrificial pattern 160a from being excessively removed, and/or their shapes from being collapsed.

A mixture ratio of O₂ gas and HBr gas may be variously changed or applied depending on the thickness of the first and second mask patterns 150 and 170b and the base resin. For example, the higher the O₂ gas content ratio becomes, the lower the selectivity between the sacrificial pattern 160a and the first and second mask patterns 150 and 170b may be, and the higher the HBr gas content ratio becomes, the longer the process time may be. In the dry etching process, corners of the first and second mask patterns 150 and 170b may be rounded.

According to embodiments of the inventive concept, when the sacrificial pattern 160a is removed using a dry etch-back process, damage to the first and second mask patterns 150 and 170b or various interfaces may be reduced or prevented. For example, when the sacrificial pattern 160a is removed using a liquid phase dissolvent, the upper portions of the sacrificial pattern 160a may not be removed and/or may require longer to be removed, and the dissolvent may infiltrate the interface between the sacrificial pattern 160a and the first and second mask patterns 150 and 170b to damage lower parts of the first and second mask patterns 150 and 170b, so that damaged patterns may be formed instead of stable patterns. As such, when the liquid phase dissolvent is used to remove the sacrificial pattern 160a, the infiltration of the dissolvent may cause the patterns to be damaged, and thus an additional process to improve adhesive properties between the first mask pattern 150 and the sacrificial layer 160, and between the sacrificial pattern 160a and the mask material layer 170 in FIGS. 2B and/or 2E, may be required. For example, an alkalescent interface treatment may be required. Therefore, since a liquid phase dissolvent is not used in embodiments of the inventive concept, undesired pattern damage may be reduced and/or prevented, and an additional process to improve adhesion properties may be omitted.

Referring to FIGS. 1A through 2J, during the etch-back process, portions of the first and second mask patterns 150 and 170b may be removed along with the sacrificial pattern 160a, so that a reduced or shrunk first mask pattern 150a and a reduced or shrunk second mask pattern 170c may be formed. That is, the first mask pattern 150 and the second mask pattern 170b in FIG. 2H may be shrunk during the etch-back process. The shape of the pattern before shrinkage/reduction is represented by a dotted line.

Referring to FIGS. 1A and 2K, anti-reflection patterns 145 may be simultaneously or continuously formed. When the anti-reflection layer 140 includes an organic material, the exposed anti-reflection layer 140 is continuously removed in the same process after removing the sacrificial pattern 160a, so that the anti-reflection patterns 145 may be formed. According to embodiments of the inventive concept, since both the sacrificial pattern 160a and the anti-reflection layer 140 include an organic material, they may be removed by one common process without an additional process. That is, both the sacrificial pattern 160a and the exposed anti-reflection layer 140 may be removed only by a dry etch-back process as described herein. Additionally, the first and second mask patterns 150a and 170c and/or anti-reflection patterns 145 may have sloped or tapered sidewalls such that their lower horizontal width is greater than their upper horizontal width.

Referring to FIGS. 1A and 2L, the methods of forming patterns according to the first embodiment may include forming a lower pattern 115 using the first and second mask patterns 150a and 170c as patterning masks (S100). The first and second mask patterns 150a and 170c and the anti-reflection layers 145 may be subsequently removed.

In the methods of forming patterns according to the first embodiment, when the first and second mask patterns 150a and 170c are formed, an organic material may be used, and the general dissolvent or developer may only be used in a small amount. When organic and inorganic materials are simultaneously used, problems attributable to adhesion properties between organic and inorganic materials, application and perception of an endpoint of a chemical mechanical polishing (CMP) methods, separate performance of processes of removing an organic material and removing an inorganic material, and/or adjustment of the sizes and heights of patterns may be present. Such problems may not be overcome or may be difficult to be overcome, and thus may have a negative effect on the overall fabrication process. Also, a liquid phase dissolvent or developer may infiltrate into the interfaces of the patterns and may damage the patterns, thereby degrading adhesion properties. Further, a rinsing process may be required, and thus the process may become more complicated. Therefore, the methods of forming patterns according to the first embodiment may stabilize the processes and improve productivity.

FIGS. 1B, 3A and 3B are a flowchart and cross-sectional views illustrating methods of forming patterns according to a second embodiment of the inventive concept. The methods of forming patterns according to the second embodiment may include forming a soluble layer 170a on the mask material layer 170 with reference to FIGS. 1B and 3A, and the thickness of the soluble layer 170a is adjusted such that the portion of the mask layer 170 that remains on the sacrificial pattern 160a is relatively thick. This result may be obtained by changing the thickness of the acid generation layer 180 and/or the conditions of the second baking process.

Referring to FIGS. 1B and 3B, the methods of forming patterns according to the second embodiment may include removing the soluble layer 170a such that the sacrificial pattern 160a is not exposed (S82). That is, a mask material layer 170′ on or covering an upper part or upper surface of the sacrificial pattern 160a may be formed. Referring to FIG. 2I, the methods may include removing an upper part of the mask material layer 170′ and the sacrificial pattern 160a to form first and second mask patterns 150 and 170b (S92). Removing the mask material layer 170′ may include an ashing process using oxygen plasma. Removing the upper part of the sacrificial pattern 160a may include performing an etch-back process including O₂ and HBr. Removing the upper part of the mask material layer 170′ and removing the sacrificial pattern 160a may be continuously or simultaneously performed. In addition, referring to FIGS. 2J through 2L, the methods may further include forming a lower pattern (S100).

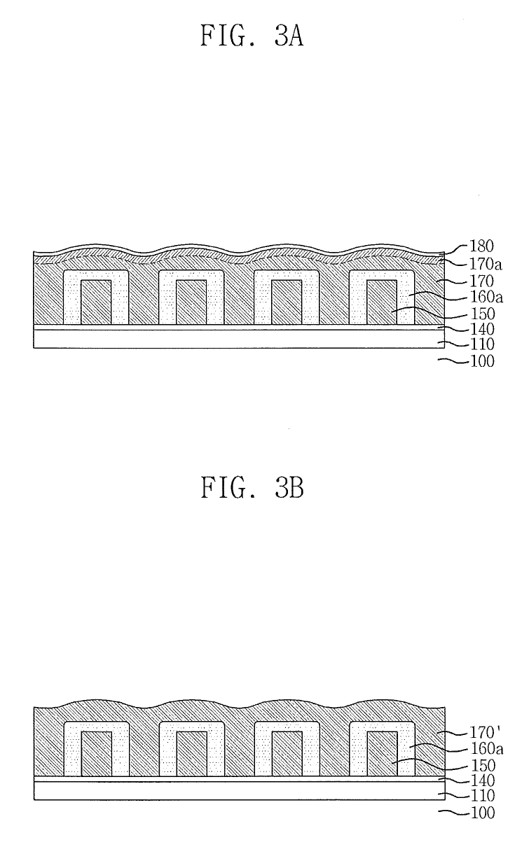

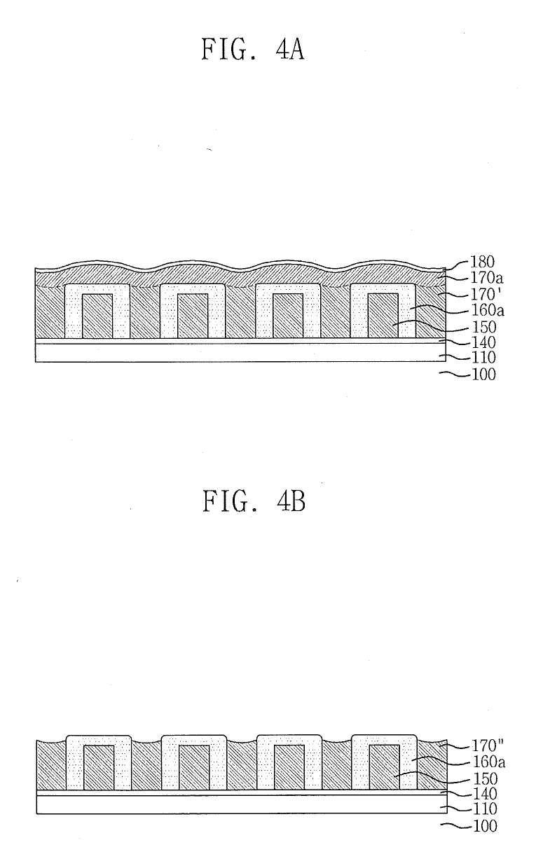

FIGS. 1C, 4A and 4B are a flowchart and cross-sectional views illustrating methods of forming patterns according to a third embodiment of the inventive concept. Referring to FIGS. 1C and 4A, the methods of forming patterns according the third embodiment may include forming an acid generation layer 180 on the mask material layer 170′ as shown in FIGS. 1 and 2F, and forming a soluble layer 170a (S73) by diffusing acid into the mask material layer 170′ such that an interface between the soluble layer 170a and the mask material layer 170′ is disposed lower than a top or upper surface of the sacrificial pattern 160a.

Referring to FIGS. 1C and 4B, the method of forming patterns according the third embodiment may include forming first and second mask patterns 150 and 170″ exposing a top or upper surface of the sacrificial pattern 160a by removing the acid generation layer 180 and the soluble layer 170a (S93).

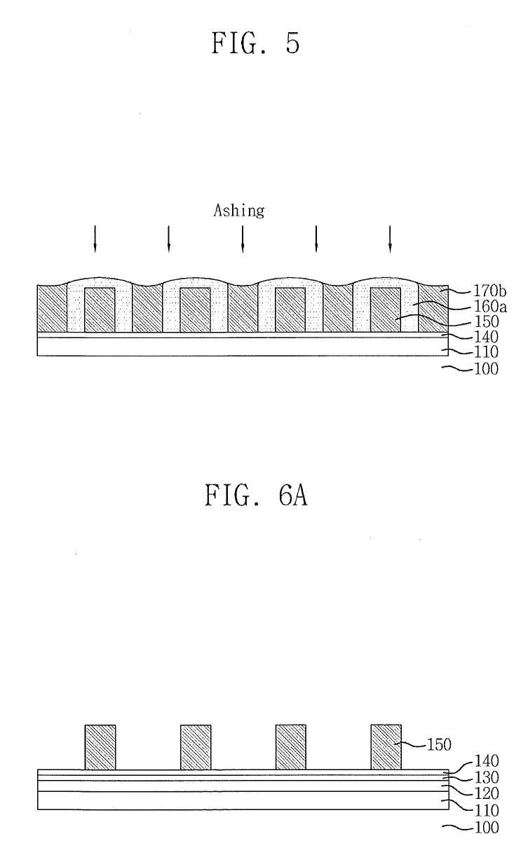

Referring to FIGS. 1D and 5, methods of forming patterns according to a fourth embodiment may include partially removing an upper part of the mask material layer 170 using an ashing method, without forming the acid generation layer 180 of FIG. 2F. In particular, the ashing may be performed after forming the mask material layer 170 covering the sacrificial pattern 160a with reference to FIGS. 1A and 2E, so that the upper part or upper surface of the sacrificial pattern 160a is exposed (S84). The ashing method may employ O₂ plasma. The processes described with reference to FIGS. 2I through 2L may be subsequently performed.

Methods of forming patterns according to embodiments illustrate that the patterns may be variously patterned according to dissolving resistance etching resistance and/or ashing resistance of the sacrificial pattern 160a and the first and second mask pattern 150, 170b.

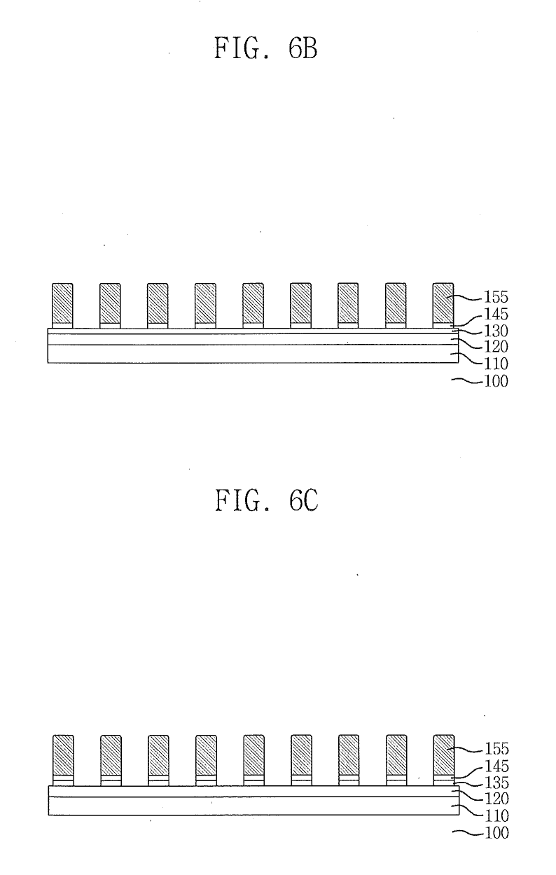

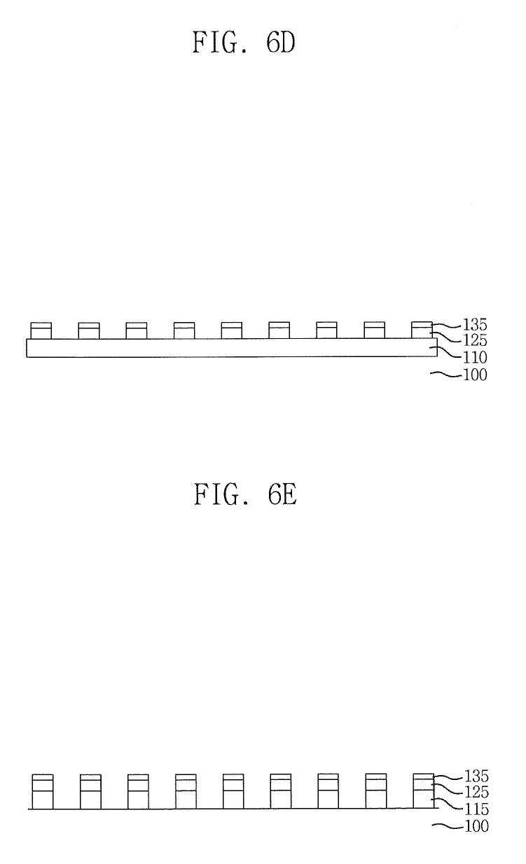

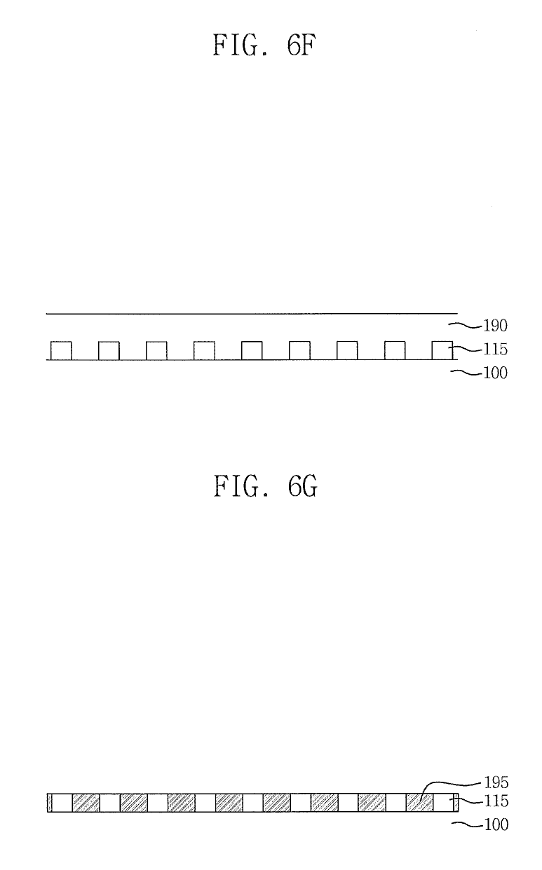

FIGS. 6A through 6G are cross-sectional views illustrating methods of forming patterns according to a fifth embodiment of the inventive concept. Referring to FIG. 6A, the methods of forming patterns according to the fifth embodiment may include forming a lower layer 110, a lower hard mask layer 120, an upper hard mask layer 130, an anti-reflection layer 140 and a first mask pattern 150 on a substrate 100. The lower hard mask layer 120 may include carbon. For example, the lower hard mask layer 120 may include an amorphous carbon layer and/or a carbon containing SOH layer. The SOH layer may contain an organic material. The upper hard mask layer 130 may include, for example, inorganic material such as silicon nitride (SiN) or silicon oxynitride (SiON). In some embodiments, only one of the lower hard mask layer 120 and the upper hard mask layer 130 may be formed. The first mask pattern 150a, the second mask pattern 170c and the anti-reflection patterns 145 may be formed with reference to FIGS. 1A through 1D, 2B through 2K, 3A and 3B, 4A and 4B, and/or 5.

Referring to FIG. 6B, the methods of forming patterns according to the fifth embodiment may include performing the processes described in FIGS. 1A through 1D, 2A through 2K, 3A and 3B, 4A and 4B, and/or 5, so that the second mask pattern 155 and the anti-reflection patterns 145 may be formed. The mask pattern 155 may include the first and second mask patterns 150a and 170c as reduced or shrunk in FIGS. 2J and 2K.

Referring to FIG. 6C, the methods of forming patterns according to the fifth embodiment may include performing an etching process using the mask pattern 155 as a patterning mask to form an upper hard mask pattern 135. Then, the mask pattern 155 and the anti-reflection patterns 145 may be removed.

Referring to FIG. 6D, the methods of forming patterns according to the fifth embodiment may include performing an etching process using the upper hard mask pattern 135 as a patterning mask to form a lower hard mask pattern 125. In some embodiments, the lower hard mask pattern 125 may be formed by an etching process in which the mask pattern 155 is used as a patterning mask.

Referring to FIG. 6E, methods of forming patterns according to the fifth embodiment may include performing an etching process using the upper hard mask pattern 135 and/or the lower hard mask pattern 125 as patterning masks to form a lower pattern 115. The upper hard mask pattern 135 and the lower hard mask pattern 125 may be subsequently removed.

Referring to FIG. 6F, methods of forming patterns according to the fifth embodiment may include forming a capping layer 190 on or covering the lower pattern 115. The capping layer 190 may include an insulating material, and may be used as an interlayer insulating layer.

Referring to FIG. 6G, in the methods of forming patterns according to the fifth embodiment, a conductive pattern 195 may be formed between the lower patterns 115 after the operations of FIG. 6E. For example, after forming a conductive layer (in a manner similar to the capping layer 190 of FIG. 6F), the conductive pattern 195 may be formed by performing a planarization process such as an etch-back process or a CMP process. In FIG. 6G, the lower pattern 115 may be an insulating material. Additionally or alternatively, an additional insulating layer may be provided between the substrate 100 and the conductive pattern 195. Further, the substrate 100 may be an insulating layer in some embodiments.

The method of forming patterns according to the fifth embodiment can enable patterns in the shape of a line, and space to be easily and finely formed.

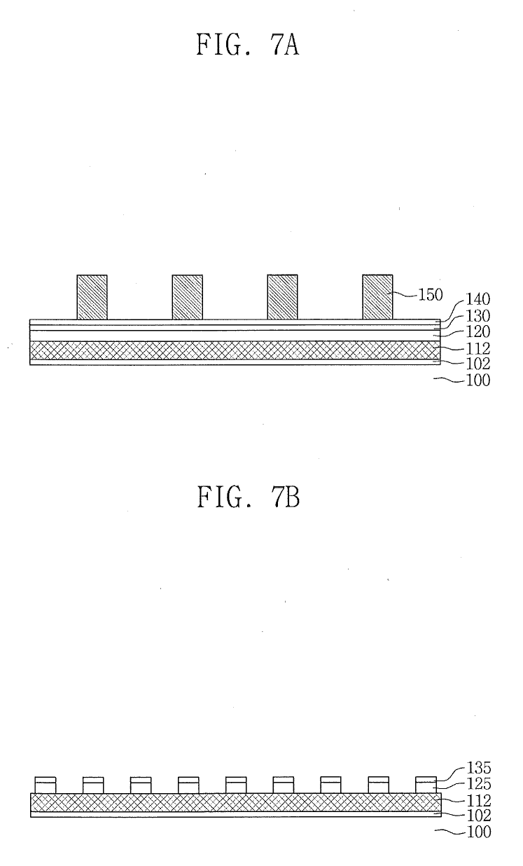

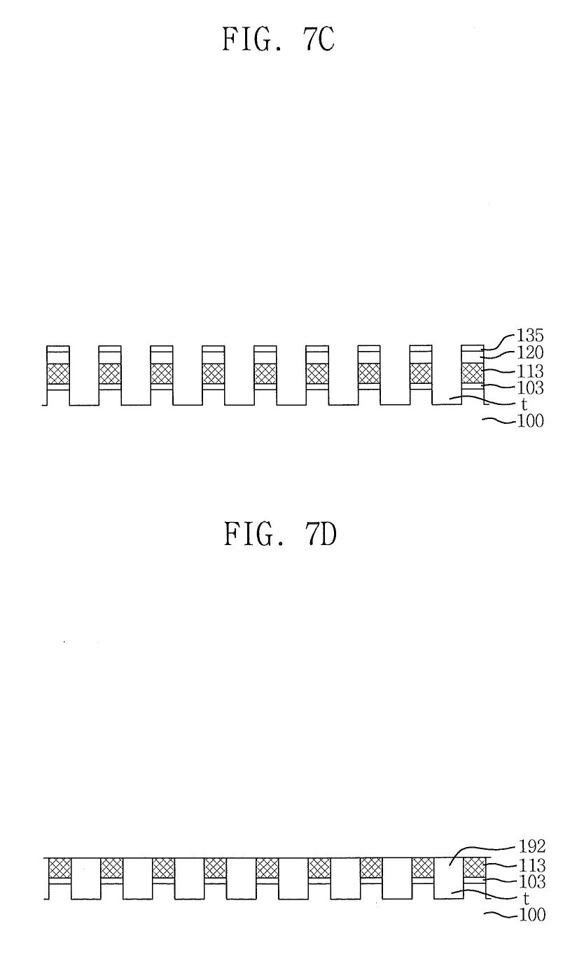

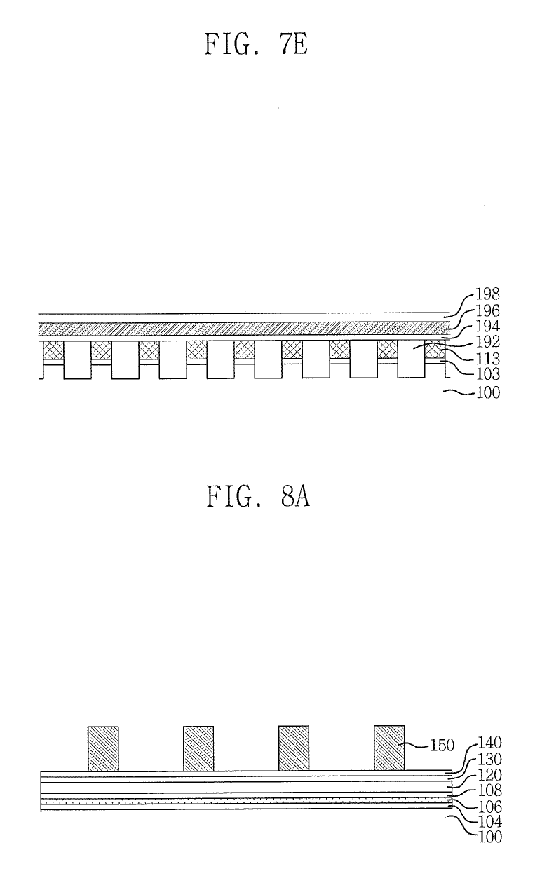

FIGS. 7A through 7E are cross-sectional views illustrating methods of forming patterns according to a sixth embodiment of the inventive concept. Referring to FIG. 7A, the methods of forming patterns according to the sixth embodiment of the inventive concept may include forming a lower insulating layer 102, a lower conductive layer 112, a lower mask layer 120, an upper mask layer 130, an anti-reflection layer 140 and first mask patterns 150. The lower conductive layer 112 may include silicon, silicide and/or metals.

Referring to FIG. 7B, the methods of forming patterns according to the sixth embodiment of the inventive concept may include forming the upper hard mask patterns 135 and the lower hard mask patterns 125 with reference to FIGS. 6A through 6D.

Referring to FIG. 7C, the methods of forming patterns according to the sixth embodiment of the inventive concept may include performing an ashing process using the upper hard mask patterns 135 and/or the lower hard mask patterns 125 as patterning masks to form lower conductive patterns 113 and lower insulating patterns 103. In addition, portions of the substrate 100 exposed by the patterns 135 and/or 125 may be removed to form trenches t. The upper hard mask patterns 135 and the lower hard mask patterns 125 may be subsequently removed.

Referring to FIG. 7D, the methods of forming patterns according to the sixth embodiment of the inventive concept may include forming an isolating insulation layer 192 between the lower conductive patterns 113 and in the trenches t. CMP may be employed such that a top surface of the isolating insulation layer 192 and top surfaces of the lower conductive patterns 113 may be equivalently or similarly formed. In other words, the top surfaces of the isolating insulation layer 192 and those of the lower conductive patterns 113 may be coplanar. Alternatively, the top surface of the isolating insulation layer 192 may be recessed to be lower than the top surfaces of the lower conductive patterns 113. The isolating insulation layer 192 may include silicon oxide such as undoped silicate glass (USG) or tonen silazene (TOSZ).

Referring to FIG. 7E, the methods of forming patterns according to the sixth embodiment of the inventive concept may include forming an intermediate insulating layer 194, an upper conductive layer 196 and a capping layer 198 on the isolating insulation layer 192 and the lower conductive patterns 113. The intermediate insulating layer 194 may include oxide, and may be further densified than the lower insulating pattern 103. The upper conductive layer 196 may include silicon, silicide, and/or metals. The capping layer 198 may include silicon oxide and/or silicon nitride.

The methods of forming patterns according to the sixth embodiment of the inventive concept may be applied to form a flash memory cell pattern having a floating gate. The methods of forming patterns according to the sixth embodiment of the inventive concept may include forming cell patterns, and forming a trench t in the substrate 100 and filling the isolating insulation layer 192, so that the method may be combined and associated with the process of defining and isolating active regions such as STI. Therefore, according to the embodiments of the inventive concept, the fabrication process may be further simplified, and thus productivity and yield may be increased.

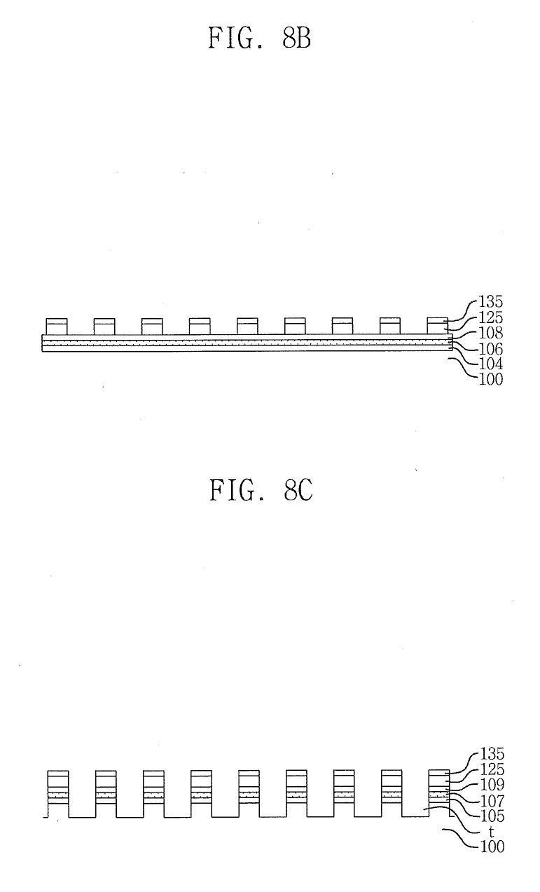

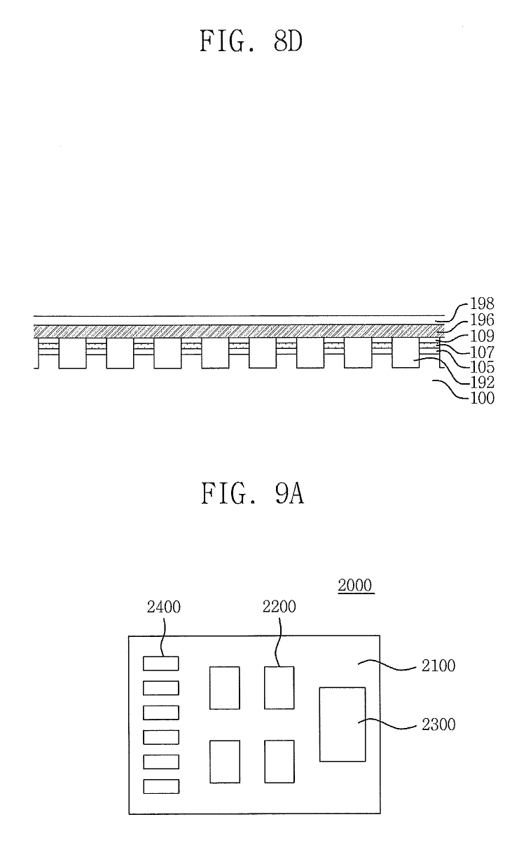

FIGS. 8A through 8D are cross-sectional views illustrating methods of forming patterns according to a seventh embodiment of the inventive concept. Referring to FIG. 8A, the methods of forming patterns according to the seventh embodiment of the inventive concept may include forming a lower trap insulating layer 104, an intermediate trap insulating layer 106, an upper trap insulating layer 108, a lower mask layer 120, an upper mask layer 130, an anti-reflection layer and first mask patterns 150 on a substrate 100. The lower trap insulating layer 104 may include silicon oxide, and the intermediate trap insulating layer 106 may include an insulating material having a higher dielectric constant than the lower trap insulating layer 104, and the upper trap insulating layer 108 may include an insulating material further densified than the lower trap insulating layer 104. For example, the lower trap insulating layer 104 may include silicon oxide, the intermediate trap insulating layer 106 may include silicon nitride, and the upper trap insulating layer 108 may include metal oxide such as aluminum oxide or tantalum oxide.

Referring to FIG. 8B, the methods of forming patterns according to the seventh embodiment of the inventive concept may include forming the upper hard mask patterns 135 and the lower hard mask patterns 125 with reference to FIGS. 6A through 6D.

Referring to FIG. 8C, the methods of forming patterns according to the seventh embodiment of the inventive concept may include performing an ashing process using the upper hard mask patterns 135 and/or the lower hard mask patterns 125 as patterning masks to form lower trap patterns 105, intermediate trap patterns 107, and upper trap patterns 109. In addition, portions of the substrate 100 exposed by the patterns 135 and/or 125 may be removed, so that the trenches t may be formed. The upper hard mask patterns 135 and the lower hard mask patterns 125 may be subsequently removed.

Referring to FIG. 8D, the methods of forming patterns according to the seventh embodiment of the inventive concept may include forming an isolation insulating layer 192 filling between the trap patterns 105, 107 and 109 and the trenches t, and forming the upper conductive layer 196 and the capping layer 198 on the isolation insulating layer 192 and the upper trap patterns 109.

The methods of forming patterns according to the seventh embodiment of the inventive concept may be applied to form a flash memory cell pattern such as a charge trap flash (CTF) memory. In the methods of forming patterns according to the seventh embodiment of the inventive concept, the trenches t are formed in the substrate 100 and the isolation insulating layer 192 is filled while the cell patterns are formed, and thus the method may be combined and associated with the process of defining and isolating active regions such as STI. Therefore, according to embodiments of the inventive concept, the fabrication process may be simplified, and thus productivity and yield may be increased.

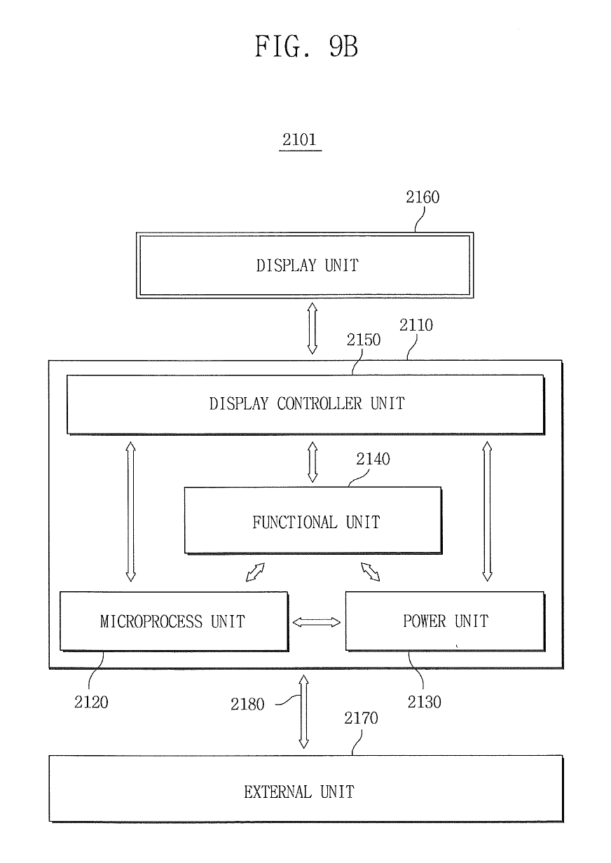

FIG. 9A is a block diagram of a semiconductor module according to some embodiments of the inventive concept. Referring to FIG. 9A, a module 2000 according to the inventive concept may include a control unit 2200, a storage unit 2300 and input/output units 2400 disposed on a module substrate 2100. The module substrate 2100 may include a PCB board. The control unit 2200 may include a logic device such as a controller. The storage unit 2300 may include memory devices such as a dynamic random access memory (DRAM), a magnetic random access memory (MRAM), and/or a NAND flash. The input/output units 2400 may include conductive terminals. At least one of the control unit 2200 and the storage unit 2300 may include the integrated circuit devices fabricated using the methods of forming patterns according to embodiments of the inventive concept. The module 2000 may be a semiconductor memory card such as a solid state disk (SSD).

FIG. 9B is a system block diagram of an electronic device according to some embodiments of the inventive concept. Referring to FIG. 9B, various stacked packages according to the inventive concept may be applied to an electronic system 2101. The electronic system 2101 may include a body 2110, a micro processor unit 2120, a power unit 2130, a function unit 2140, and a display controller unit 2150. The body 2110 may be a system board or main board formed of a PCB. The micro processor unit 2120, the power unit 2130, the function unit 2140, and the display controller unit 2150 may be mounted or installed on the body 2110. A display unit 2160 may be mounted on a surface of the body 2110 or outside the body 2110. For example, the display unit 2160 may be disposed on a surface of the body 2110 to display an image processed by the display controller unit 2150.

The power unit 2130 is supplied with a predetermined voltage from an external power supply, and divides the voltage into a required voltage level to supply to the micro processor unit 2120, the function unit 2140 and the display controller unit 2150. The micro processor unit 2120 may be supplied with a voltage from the power unit 2130 to control the functional unit 2140 and the display unit 2160. The function unit 2140 may perform various functions of the electronic system 2100. For example, when the electronic system 2100 is a cellular phone, the functional unit 2140 may include various components capable of wireless communication functioning as a cellular phone such as dialing, outputting an image on the display unit 2160 as a result of communication with an external apparatus 2170, and outputting voice through a speaker. Furthermore, when the external apparatus 2170 includes a camera, the function unit 2140 may function as a camera image processor.

In some embodiments, when the electronic system 2101 is connected to a memory card for capacity expansion, the function unit 2140 may be a memory card controller. The function unit 2140 may transmit/receive a signal to/from the external apparatus 2170 via a wired or wireless communication unit 2180. Moreover, when the electronic system 2101 requires a universal serial bus (USB) for function expansion, the functional unit 2140 may function as an interface controller.

At least one of the micro processor unit 2120 and the function unit 2140 may include the semiconductor or integrated circuit devices fabricated in accordance with various embodiments of the inventive concept.

Names and functions of elements that are not identified by reference numerals or are identified only by reference numerals in the drawings may be easily understood with reference to the other drawings and the descriptions thereof.

According to embodiments of the inventive concept, patterns with a more uniform size can be formed. According to embodiments of the inventive concept, even though materials may have less selectivity, fine patterns can be uniformly formed compared to the generally known techniques. According to embodiments of the inventive concept, use of a dissolvent may be reduced and improved results may be obtained by a more simplified process compared to the generally known techniques, and thus productivity and yield of a semiconductor device can be improved. According to embodiments of the inventive concept, since water and oxygen are mainly used, a semiconductor fabrication process can be improved in an environmentally-friendly manner.

The foregoing is illustrative of embodiments and is not to be construed as limiting thereof. Although a few embodiments have been described, those skilled in the art will readily appreciate that many modifications are possible without materially departing from the novel teachings and advantages. Accordingly, all such modifications are intended to be included within the scope of this inventive concept as defined in the claims.

What is claimed is:

1. A method of fabricating patterns in an integrated circuit device, the method comprising:
forming first mask patterns, sacrificial patterns, and second mask patterns on a target layer such that the sacrificial patterns are provided between sidewalls of adjacent ones of the first and second mask patterns;
selectively removing the sacrificial patterns between the sidewalls of the adjacent ones of the first and second mask patterns using a dry etch-back process; and
patterning the target layer using the first and second mask patterns as a mask.

2. The method of claim 1, wherein one or more of the first mask patterns, the second mask patterns, and the sacrificial patterns comprise organic materials, and wherein the sacrificial patterns have a lower carbon content and/or a higher oxygen content than the first mask patterns.

3. The method of claim 1, wherein the dry etch-back process comprises a plasma etch-back process using oxygen and hydrogen bromide or chlorine.

4. The method of claim 1, wherein the first mask patterns comprise a photoresist material containing an acid or generator thereof, wherein the second mask patterns comprises a material having a dry etching resistance similar to that of the first mask patterns, and wherein the sacrificial patterns comprise a material configured to react with the acid to form an ionic bond.

5. The method of claim 1, wherein forming the sacrificial patterns comprises:
forming a sacrificial layer on upper surfaces and sidewalls of the first mask patterns;
processing the first mask patterns and the sacrificial layer thereon such that the acid diffuses into portions of the sacrificial layer on the upper surfaces and sidewalls of the first mask patterns and reacts therewith; and
selectively removing unreacted portions of the sacrificial layer to define the sacrificial patterns along the upper surfaces and sidewalls of the first mask patterns.

6. The method of claim 5, wherein the sacrificial layer includes a water soluble polymeric organic compound containing carbon, nitrogen, and/or hydrogen.

7. The method of claim 6, wherein the water soluble polymeric organic compound contains pyrrolidone or imidazole.

8. The method of claim 5, wherein forming the first mask patterns comprises photolithographically forming the first mask patterns, and further comprising:
forming an anti-reflective layer comprising an organic material on the target layer prior to forming the first mask patterns thereon,
wherein selectively removing the sacrificial patterns further removes portions of the anti-reflective layer thereon.

9. The method of claim 1, wherein forming the second mask patterns comprises:
forming a second mask layer on the first mask patterns and the sacrificial patterns;
forming an acid generation layer on the second mask layer;
processing the acid generation layer and the second mask layer such that acid diffuses into portions of the second mask layer and reacts therewith to define a soluble layer; and
removing the acid generation layer and the soluble layer to define the second mask patterns.

10. The method of claim 9, wherein removing the soluble layer comprises:
selectively removing the soluble layer using a chemical etch-back process including alkali chemicals or developers containing tetramethylammonium hydroxide (TMAH).

11. The method of claim 10, wherein the first and second mask patterns have a higher dissolving resistance to the alkali chemicals than the sacrificial patterns.

12. The method of claim 1, wherein the target layer includes at least one hard mask layer and a lower layer on a substrate, wherein patterning the target layer comprises:
patterning the at least one hard mask layer using the first and second mask patterns to define hard mask patterns on the lower layer; and
patterning the lower layer using the hard mask patterns to define lower layer patterns.

13. The method of claim 12, further comprising:
patterning the substrate using the hard mask patterns as a mask to define trenches therein;
forming isolating insulation patterns in the trenches between adjacent ones of the lower layer patterns; and
forming an upper conductive layer on the lower layer patterns and the isolating insulation patterns.

14. The method of claim 13, wherein the lower layer patterns respectively comprise a lower insulating pattern and a lower conductive pattern thereon, and further comprising:
forming an intermediate insulating layer on the lower conductive patterns and the isolating insulation patterns prior to forming the upper conductive layer thereon.

15. The method of claim 14, wherein the lower layer patterns respectively comprise a stack including a lower trap insulating pattern, an intermediate trap insulating pattern, and an upper trap insulating pattern.

16. A method of forming patterns, the method comprising:
forming a lower layer on a substrate;
forming first mask patterns on the lower layer;
forming sacrificial patterns on surfaces of the first mask patterns;
forming second mask patterns between the sacrificial patterns;
removing the sacrificial patterns using a dry etch-back process to expose the first mask patterns;
patterning the lower layer using the first and second mask patterns as masks to form lower patterns; and
removing the first and second mask patterns,
wherein the first and second mask patterns and the sacrificial pattern contain an organic material.

17. The method of claim 16, wherein forming the second mask patterns comprises:
forming a mask material layer on the sacrificial patterns; and
removing upper parts of the mask material layer and exposing upper parts of the sacrificial patterns, and
wherein removing the upper parts of the mask material layer comprises:
forming an acid generation layer containing acid or potential acid on the mask material layer;
generating acid in the acid generation layer;
diffusing the generated acid into the mask material layer, and forming a soluble layer; and
removing the soluble layer.

18. The method of claim 17, wherein the potential acid includes a thermo acid generator (TAG), and wherein generating acid in the acid generation layer and diffusing the generated acid into the mask material layer include using a baking process.

19. The method of claim 18, wherein the baking process includes placing the substrate including the acid generation layer thereon in a bake oven having a lower temperature than a glass-transition temperature of the mask material layer for about thirty seconds to about two minutes.

20. A method of forming patterns, the method comprising:
forming a lower layer on a substrate;
forming a hard mask layer on the lower layer;
forming a first mask pattern, a second mask pattern spaced apart from the first mask pattern, and a sacrificial pattern between the first and second mask patterns on the lower layer, wherein the first and second mask patterns and the sacrificial pattern comprise an organic material;
removing the sacrificial pattern using a gas plasma process containing oxygen and remaining the first and second mask patterns;
patterning the hard mask layer using the first and second mask patterns as masks to form a hard mask pattern; and
patterning the lower layer using the hard mask pattern as a mask to form a lower pattern.
